(19) United States
(12) Patent Application Publication
(10) Pub. No.: US 2026/0068754 A1
(43) Pub. Date: Mar. 5, 2026

(54) SEMICONDUCTOR DEVICE WITH STRUCTURALLY REINFORCED CORNERS

(71) Applicant: Sandisk Technologies, Inc., Milpitas, CA (US)

(72) Inventor: Yangming Liu, Shanghai (CN)

(73) Assignee: Sandisk Technologies, Inc., Milpitas, CA (US)

(21) Appl. No.: 18/825,864

(22) Filed: Sep. 5, 2024

(51) Int. Cl. H01L 25/16; H01L 23/498; H01L 23/538

(52) U.S. Cl. CPC H01L 25/162; H10D 1/68

(57) ABSTRACT

A semiconductor device is mounted to a printed circuit board by one or more capacitor. The capacitors provide a dual function of electrically and mechanically supporting the semiconductor device. Multiple semiconductor devices are formed on a panel of substrates. Support vias are formed in the saw street between adjacent substrate instances, at the corners of each substrate instance. Portions of these support vias remain at the corners of each semiconductor device when the devices are singulated from the panel. These portions of the support vias are used to bond the semiconductor devices to the capacitors on the printed circuit board.

### BACKGROUND

The strong growth in demand for portable consumer electronics is driving the need for high-capacity storage devices. Non-volatile semiconductor memory devices are now widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, computer SSDs, PDAs and cellular telephones.

While many varied packaging configurations are known, flash memory semiconductor devices may in general be fabricated as system-in-a-package (SIP) or multichip modules (MCM), where a plurality of semiconductor die are mounted and interconnected to an upper surface of a small footprint substrate. The substrate may in general include a rigid, dielectric base having a conductive layer etched on one or both sides. Solder balls are often mounted on contact pads formed on a lower surface of the substrate to allow the substrate to be soldered to a host device such as a printed circuit board. Once mounted, signals may be transferred between the semiconductor die and the host device via the substrate.

In conventional semiconductor devices, mechanical stresses are often generated at the solder ball junction between substrate pads and the PCB (printed circuit board) pads. In particular, it has been observed that solder balls, particularly those located at the corners of the semiconductor device, are prone to dislodging during thermal cycling, resulting in board level reliability (BLR) failure and loss of electrical connectivity. These dislodging stresses can also be generated as a result of impact shock to the solder balls, for example during handling or drop testing of the semiconductor device.

### DESCRIPTION OF THE DRAWINGS

FIG. 1 is a flowchart of the overall assembly process of a semiconductor device according to embodiments of the present technology.

FIG. 2 is a top view of a panel of substrates used in forming semiconductor devices according to embodiments of the present technology.

FIG. 3 is a top view of a substrate used in forming semiconductor devices according to embodiments of the present technology.

FIG. 4 is a bottom view of a substrate used in forming semiconductor devices according to embodiments of the present technology.

FIG. 5 is a cross-sectional edge view of a substrate used in forming semiconductor devices according to embodiments of the present technology.

FIG. 6 is a perspective view of a substrate used in forming semiconductor devices according to embodiments of the present technology.

FIG. 7 is a cross-sectional edge view of a substrate used in forming semiconductor devices according to alternative embodiments of the present technology.

FIG. 8 is a cross-sectional edge view of a semiconductor device during assembly according to an embodiment of the present technology.

FIG. 9 is a cross-sectional edge view of a completed semiconductor device according to an embodiment of the present technology.

FIG. 10 is a cross-sectional edge view of a semiconductor device mounted to a printed circuit board by capacitors according to embodiments of the present technology.

FIG. 11 is an enlarged cross-sectional view of a capacitor supporting a semiconductor device on a printed circuit board according to embodiments of the present technology.

FIGS. 12-17 are perspective views of a semiconductor device mounted to a printed circuit board by capacitors according to different embodiments of the present technology.

### DETAILED DESCRIPTION

The present technology will now be described with reference to the figures, which in embodiments, relate to a BGA (ball grid array) semiconductor device mounted to a printed circuit board by one or more capacitors. The capacitors provide a dual function of electrically and mechanically supporting the semiconductor device. The capacitors electrically support the semiconductor device by for example reducing inductance and noise and improving high-frequency performance. The capacitors mechanically support the semiconductor devices by providing a large bonding area at the corners where the semiconductor device is bonded to the printed circuit board.

Multiple semiconductor devices are formed on a panel of substrates. In accordance with further aspects of the present technology, filled vias, referred to herein as support vias, are formed in the saw street between adjacent substrate instances, at the corners of each substrate instance. Portions of these support vias remain at the corners of each semiconductor device when the devices are singulated from the panel. These portions of the support vias are used to bond the semiconductor devices to the capacitors on the printed circuit board.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” “upper” and “lower” and “vertical” and “horizontal” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is 0.15 mm or alternatively ±2.5% of a given dimension.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other. When a first element is referred to as being directly connected, affixed, mounted or coupled to a second element, then there are no intervening elements between the first and second elements (other than possibly an adhesive or melted metal used to connect, affix, mount or couple the first and second elements).

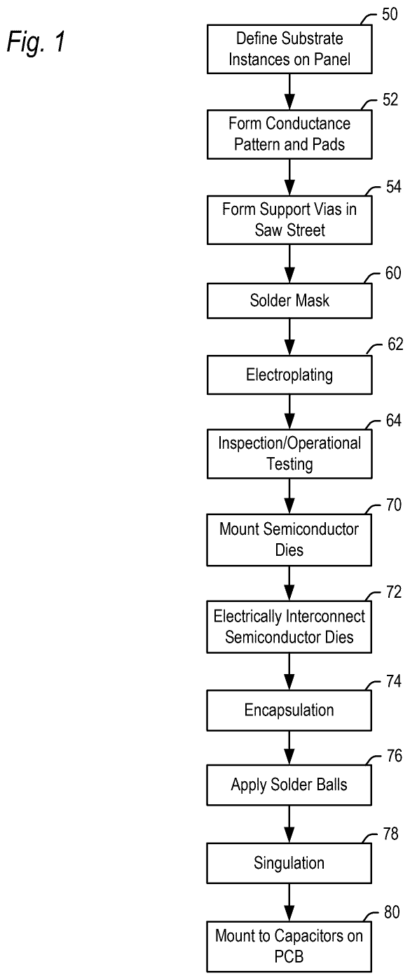

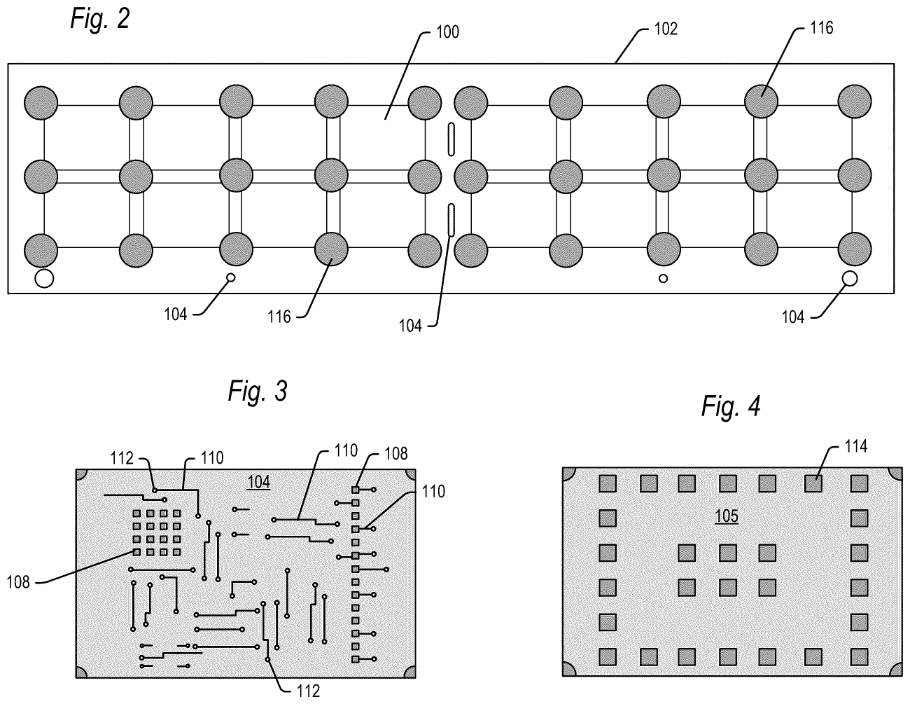

An embodiment of the present technology will now be explained with reference to the flowchart of FIG. 1 and the edge, top, bottom and perspective views of FIGS. 2 through 17. The assembly of a semiconductor device according to the present technology begins with a plurality of substrates 100 formed contiguously on a panel 102 in step 50 as shown in the top view of FIG. 2. FIG. 2 shows one representation of a panel 102 of substrates 100, though panel 102 may have a wide variety of other configurations and numbers of substrates 100 in further embodiments. Fiducial marks 103 are provided on the substrate panel 102 to allow machine vision alignment of the substrate panel in a processing tool. Again, the fiducial marks are by way of example only and may vary in other substrate panels.

The substrate 100 is an example of a chip carrier medium provided to transfer signals, data and/or information between one or more semiconductor dies mounted on the chip carrier medium and a host device as explained below. Other examples of chip carrier mediums may be used, including a printed circuit board (PCB), a leadframe or a tape automated bonded (TAB) tape. The substrate may be formed of one or more core layers, each sandwiched between conductive layers. The conductive layers may be formed of copper or copper alloys, plated copper or plated copper alloys, Alloy 42 (42Fe/58Ni), copper plated steel, or other metals and materials suitable for use on substrate panels. The one or more core layers may be formed of various dielectric materials such as for example, polyimide laminates, epoxy resins including FR4 and FR5, bismaleimide triazine (BT), and the like. The one or more core layers may be ceramic or organic in alternative embodiments.

The substrate 100 may include a first, or top, major planar surface 105 shown in FIG. 3, and a second, or bottom, major planar surface 106 shown in FIG. 4. The external conductive layers on the first and second major planar surfaces 105, 106 may be etched into conductance patterns comprising electrical connectors in step 52. In one example shown in FIG. 3, the electrical connectors in the first major surface 105 may include contact pads 108 for physically and electrically attaching semiconductor dies to the substrate 100 as explained below. The surface 104 (as well as possibly one or more intermediate layers within the substrate 100) may further be processed to include conductive traces 110 and vias 112. The traces 110 and vias 112 may be coupled with the contact pads 108 to transfer electrical signals between the semiconductor dies and a host PCB through the substrate as explained below. The pattern and number of contact pads 108, electrical traces 110 and vias 112 are provided by way of example only and each may vary in further embodiments.

The bottom surface 105 of the substrate shown in FIG. 4 may include a pattern of contact pads 114 for receiving solder balls as explained below. The pattern and number of contact pads 114 shown in FIG. 4 is by way of example only and may vary in further embodiments.

In accordance with further aspects of the present technology, filled support vias 116 may be formed at the corners between each substrate instance on panel 102 in step 54 as shown in FIG. 2. The support vias 116 may be formed in the saw streets 118. The saw streets 118 are the spaces between each substrate 100 which largely or entirely gets removed when the finished semiconductor devices formed on substrates 100 are singulated from the panel 102 as explained below. Each support via 116 may include a filled via formed perpendicularly down through the substrate panel 102, and may include a land formed on the top and/or bottom surface of the via of slightly larger diameter. In embodiments, the support vias may be formed of copper, but may be formed of other materials in further embodiments.

The support vias 116 are sized at the junction between for adjacent substrates so that a portion each support via 116 extends into each substrate at the corners. For example, a saw street 118 may have a diameter of 0.4 mm, and a support via 116 may have a diameter of 0.6 mm, with lands on the top and/or bottom of the via of a slightly larger diameter, such as for example 0.8 mm. These dimensions are by way of example only, and may vary in further embodiments, with the understanding that the support via 116 has a larger diameter than the saw street so that a portion of a support via 116 extends into the corners of the four adjacent substrates, as shown in FIGS. 3 and 4. This portion at each of the substrate corners is referred to as support via portion 120. Each substrate 100 may include the support via portion 120 at each of its four corners. However, in further embodiments, a smaller number of support vias 116 may be used so that each substrate includes a support via portion 120 at less than all four corners.

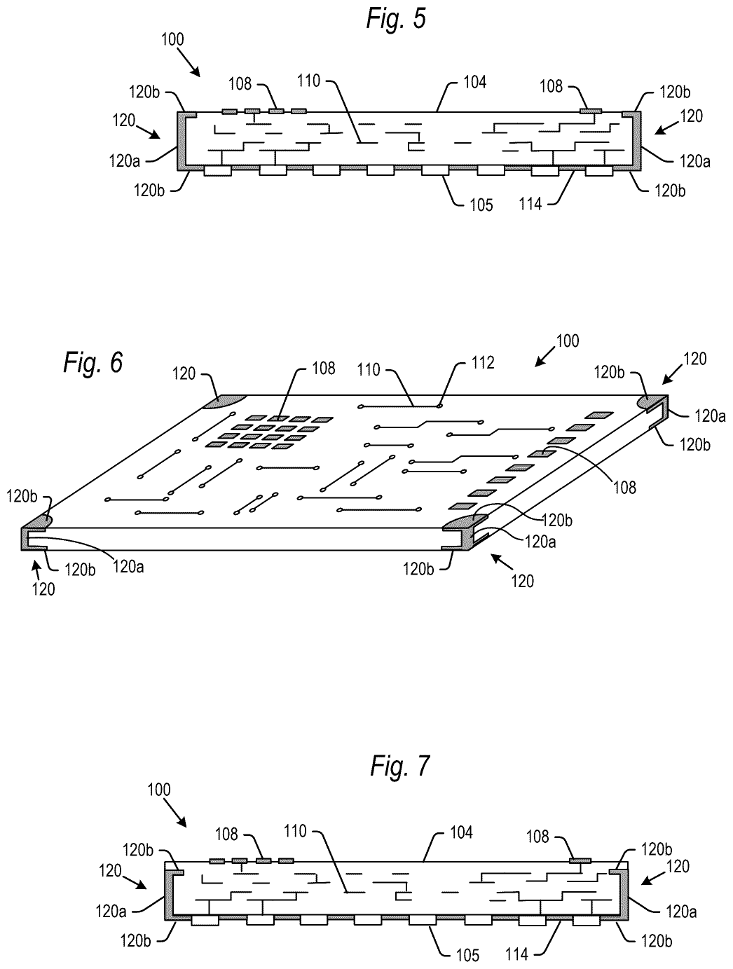

The substrates 100 are singulated from the panel 102 after they are assembled into a semiconductor device including semiconductor dies as explained below, but FIGS. 5 and 6 are cross-sectional edge and perspective views of an individual substrate 100. As shown, each substrate 100 includes support vias portions 120 at its corners. Each support via portion includes a via portion 120a and land portions 120b at its top and/or bottom. As noted, the land portions 120b may be slightly larger than the via portions 120a.

In FIGS. 5 and 6, the via portions 120a extend through the entire thickness of the substrate 100 so that the land portions 120b are located on the top and bottom major planar surfaces 104 and 105. In a further embodiment shown in FIG. 7, the via portion 120a may be formed only partially through the substrate thickness. In the embodiment shown, the bottom land portion 120b is on the bottom surface 105 of the substrate 100, but the top land portion 120b is buried within an interior surface of the substrate 100. The support vias 116 may be formed in the saw streets 118 at the same time as the traces 110 and/or vias 112 are formed on the substrates 100. In further embodiments, the support vias 116 may be formed in the saw streets 118 before or after the traces 110 and/or vias 112 are formed on the substrates 100.

The substrate 100 may undergo a variety of further processing steps, including solder masking (step 60), electroplating of exposed contact pads (step 62) on surfaces 104, 105, and inspection and operational testing (step 64). At least some of the above-described steps may be performed in different orders, and additional or alternative processing steps are contemplated.

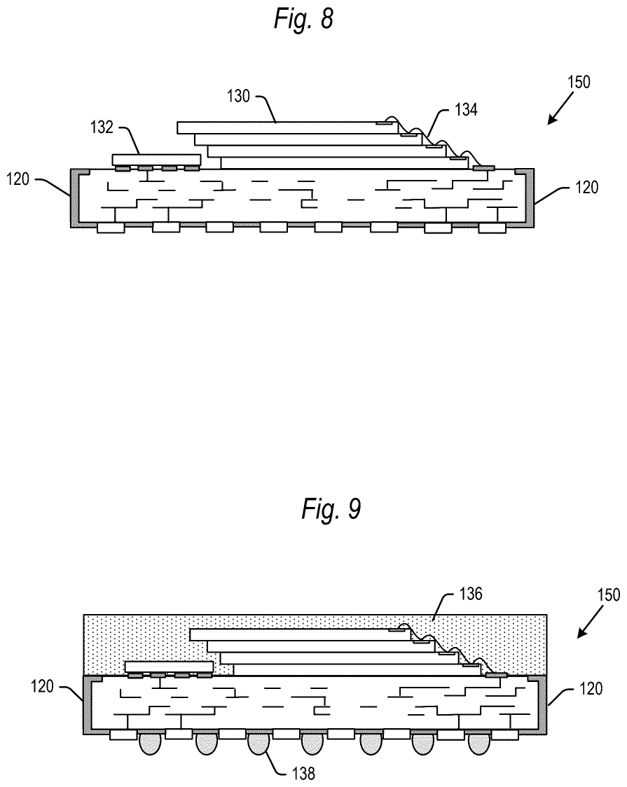

In step 70, one or more semiconductor dies may be mounted to the first major planar surface 104 of substrate 100 as shown for example in the cross-sectional edge view of FIG. 8. The addition of the semiconductor dies to the substrate may form a semiconductor device 150. The one or more semiconductor dies may comprise a stack of memory dies 130 and a controller die 132. The memory dies may for example be non-volatile flash memory dies such as 2D NAND flash memory or 3D BiCS (Bit Cost Scaling), V-NAND or other 3D flash memory, but other types of dies 130 may be used. These other types of memory dies include but are not limited to RAM such as an SDRAM, DDR SDRAM, LPDDR and GDDR. The controller die 132 may for example be an ASIC, but other types of controller dies may be used, including for example high powered processors such as AI processors or graphics processing units. The semiconductor device 150 shown in FIG. 8 includes both memory dies 130 and a controller die 132. However, it is understood that the semiconductor device 150 may comprise memory dies 130 without the controller die 132, or it ma comprise the controller die 132 without the memory dies 130.

Where multiple semiconductor dies 130 are included, the semiconductor dies 130 may be stacked atop each other in an offset stepped configuration to form a die stack as shown in FIG. 8. The number of dies 130 shown in the stack is by way of example only, and embodiments may include different numbers of semiconductor dies, including for example 1, 2, 4, 8, 16, 32 or 64 dies. There may be other numbers of dies in further embodiments. The dies 130 may be affixed to the substrate and/or each other using a die attach film (DAF) layer. As one example, the die attach film may be cured to a B-stage to preliminarily affix the dies 130 in the stack, and subsequently cured to a final C-stage to permanently affix the dies 130 to the substrate 100.

In step 72, the semiconductor memory dies 130 may be electrically interconnected to each other and to the contact pads 108 of the substrate 100. FIG. 8 shows bond wires 134 formed between corresponding die bond pads on respective dies 130 down the stack, and then bonded to contact pads 108 on the top surface 104 of the substrate 100. The bond wires 134 may be formed by a ball-bonding technique, but other wire bonding techniques are possible. The semiconductor dies 130 may be electrically interconnected to each other and the substrate 100 by other methods in further embodiments, including by through-silicon vias (TSVs) and flip-chip technologies. The controller die 132 may be affixed to the contact pads 108 on the substrate by flip-chip bonding, but other techniques may be used including wire bonding.

In step 74, the panel 102 of semiconductor devices 150 may be encapsulated in a mold compound 136 as shown in the cross-sectional edge view of FIG. 9. Mold compound 136 may include for example solid epoxy resin, Phenol resin, fused silica, crystalline silica, carbon black and/or metal hydroxide. Other mold compounds are contemplated. The mold compound 136 may be applied by various known processes, including by FFT (flow free thin) molding, compression molding, transfer molding or injection molding techniques.

In step 76 solder balls 138 may be applied to the contact pads 114 on the bottom major planar surface 105 of substrate 100 as shown for example in FIG. 9. It is understood that the solder balls 138 may be applied earlier in the assembly of the semiconductor device 150.

After assembly and encapsulation of the semiconductor devices 150, the semiconductor devices 150 may be singulated from each other and panel 102 in step 78 to form individual finished semiconductor devices 150, such as the one shown in the cross-sectional edge view of FIG. 9. The semiconductor devices 150 may be singulated by any of a combination of cutting methods including sawing, water jet cutting, laser cutting, water guided laser cutting, dry media cutting, and diamond coating wire cutting.

As noted above, the support vias 116 are formed in the saw streets 118 (FIG. 2), at the corners of the substrates 100. The singulation step 78 may remove portions of the support vias 116 residing in the saw streets 118. However, as noted, the singulation step leaves support via portions 120 exposed at the corners of the singulated semiconductor devices 150.

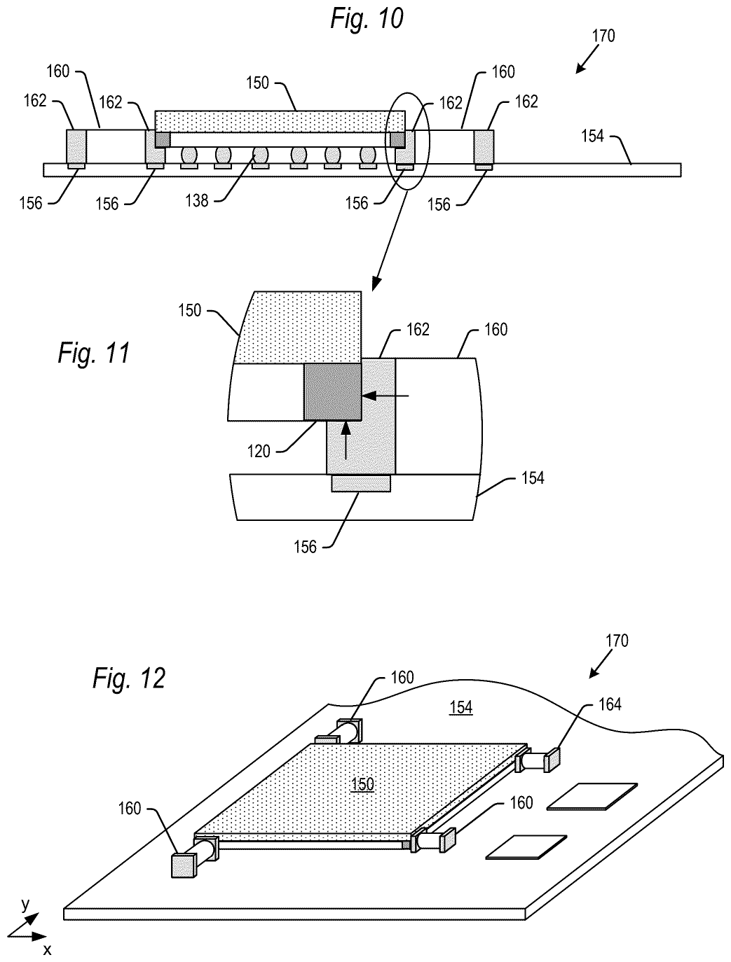

Upon completion, one or more semiconductor devices 150 may be mounted to a host device such as a printed circuit board (PCB) in step 80. FIGS. 10-16 are cross-sectional edge, enlarged cross-sectional edge and perspective views of a single semiconductor device 150 mounted on a PCB 154. The PCB 154 may be formed of one or more core layers, each sandwiched between conductive layers. The solder balls 138 mate with contact pads in the PCB to electrically and structurally couple the semiconductor device 150 to the PCB. However, as noted in the Background section, solder balls, particularly those at corners of the device, tend to dislodge under thermal and mechanical stresses. In order to address the shortcomings of relying solely on solder balls for mechanical support, the present technology further incorporates capacitors 160 at the corners of the semiconductor device 150. The capacitors 160 not only contribute to the electrical function of the circuit including semiconductor device 150, but also serve as key mechanical support elements, reinforcing the mounting of the semiconductor device 150 on the PCB 154. The semiconductor device 150, PCB 154 and capacitors 160 may together be referred to herein as semiconductor assembly 170.

Each capacitor 160 may include solder end posts 162, which are the conductive terminals that connect the capacitor 160 to the PCB 154. The solder end posts 162 of the capacitors 160 are electrically connected to corresponding contact pads 156 on the PCB 154, allowing the capacitors 160 to perform their electrical functions. For example, one or more of the capacitors 160 may be used as a decoupling capacitor, to smooth out fluctuations in the power supply and reduce impedance of the signal paths including semiconductor device 150. One or more of the capacitors 160 may act as a bypass capacitor, filtering out high-frequency noise which otherwise may impede high-frequency data transfer to/from the semiconductor device. The capacitors 160 may further reduce cross-talk between high-frequency data lines on a PCB. The capacitors 160 may serve other electrical and signal transmission functions in further embodiments.

In addition to their electrical function, the capacitors 160 are designed to provide significant structural and mechanical support to the semiconductor device 150 on PCB 154. During the reflow soldering process (explained below), the corners of the semiconductor device 150, which are particularly vulnerable to mechanical stress, are positioned directly above the solder end posts 162 of the capacitors 160. As the reflow process progresses, the solder material at the end posts melts and forms a molten pool around the corners of the semiconductor device. When the assembly cools and the solder solidifies, the corners of the semiconductor device 150 become embedded within the solder end posts 162.

This embedding creates a robust mechanical bond between the semiconductor device 150 and the capacitors 160, effectively anchoring the device 150 to the PCB 154 at its most vulnerable points, i.e., the corners. In particular, as shown for example in the enlarged view of FIG. 11, the support via portion 120 on the semiconductor device 150 embeds within and bonds to the solder end post 162. As indicated by the arrows in FIG. 11, embedding and bonding of the support via portion 120 within the solder end post 162 provides both vertical (direction of gravity) and lateral support to prevent horizontal or lateral movement of the semiconductor device 150 relative to the capacitor 160. The mechanical support provided by the capacitors prevents the semiconductor device from experiencing movement or excessive stress, which could otherwise lead to the dislodging of the solder balls. In embodiments, the solder end posts 162 of capacitors 160 may be conventional solder end posts. In further embodiments, the solder end posts 162 may be bulked up with additional solder to provide an even stronger mechanical bond for the corners of the semiconductor device 150.

In addition to mechanical and electrical support, the capacitors 160 can also assist in thermal management. In particular, by providing a solid mechanical connection at the corners, the capacitors may help dissipate heat away from the semiconductor device 150, potentially improving the thermal performance of the semiconductor device 150.

During assembly, the capacitors 160 may be positioned on the PCB 154, and thereafter the semiconductor device may be positioned on the PCB 154, between the capacitors 160. Thereafter, the semiconductor device 150, PCB 154 and capacitors 160 may be heated in a reflow process. In one example, the reflow process may be performed at 220 to 250° C., for a period of 40 to 80 seconds. However, it is understood that both the temperature range and time duration for the reflow process may vary in further embodiments. During the reflow process, the solder balls 138 may soften and diffuse with contact pads on the PCB to electrically couple the semiconductor device 150 to the PCB 200. Additionally, the solder end posts 162 may soften and diffuse so that the support via portions 120 embed within the solder end posts. The softening of the solder end posts 162 also electrically couple the solder end posts to the contact pads 156 on PCB 154.

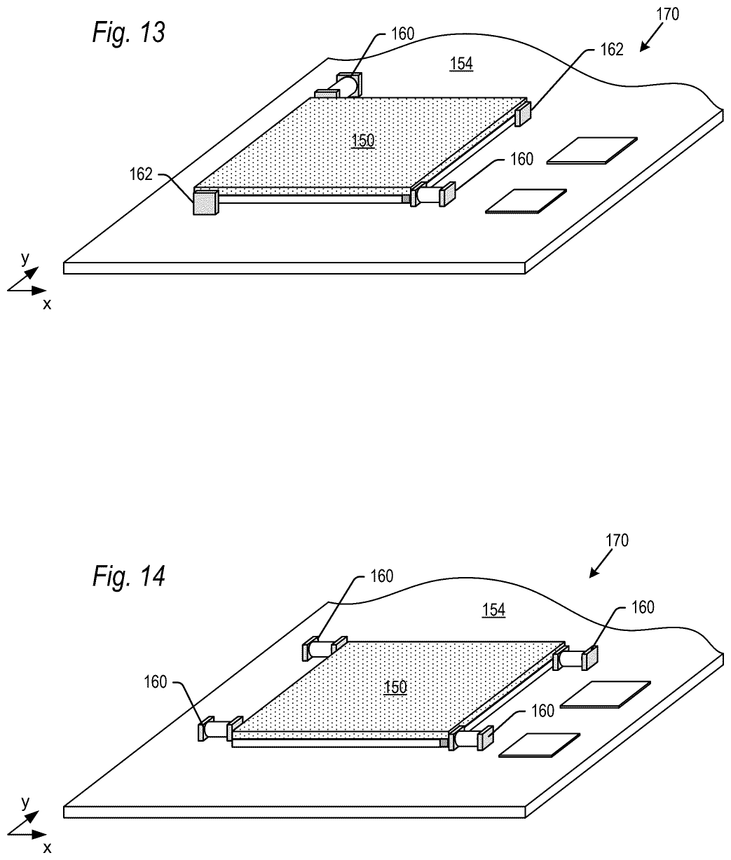

FIGS. 12-16 show different examples of a semiconductor device 150 mounted to PCB 154 by capacitors 160 at the corners of the semiconductor device 150. In the example of FIG. 12, the semiconductor device 150 includes four capacitors 160, one at each corner of the device 150. In further embodiments, it is possible that there is a capacitor 160 at only a single corner, two adjacent or opposed corners or three corners. While embodiments include a full capacitor at the one or more corners, it is possible that just the solder end post 162 by itself may be used in one or more corners. Such an embodiment is shown in FIG. 13, which is shown including a pair of capacitors 160 and a pair of solder end posts 162 by themselves. Other combinations of full capacitors 160 and end posts 162 are possible. Moreover, one or more of the capacitors 160 used may be ‘dummy’ capacitors. That is, the capacitors do not serve any electrical function (and may have no electrical connection to a circuit through the PCB. In such embodiments, the dummy capacitors serve only mechanical support functions as explained above. In FIG. 12, one of the capacitors is a dummy capacitor (dummy capacitor 164).

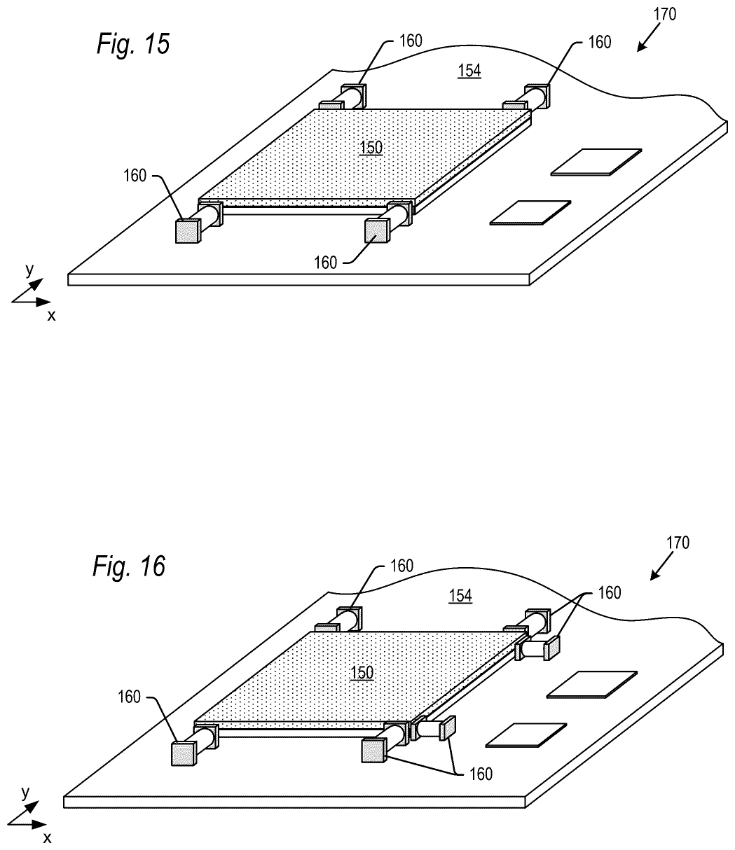

The embodiment of FIG. 12 shows two capacitors oriented along the x-axis, and two capacitors oriented along the y-axis. However, each of the capacitors at the corners may be oriented along either the x-axis or y-axis. For example, FIG. 14 shows all of the capacitors oriented along the x-axis, and FIG. 15 shows all of the capacitors oriented along the y-axis.

The embodiment of FIG. 12 shows a single capacitor at each corner of the semiconductor device 150. In further embodiments, there may be two capacitors 160 at one or more corners. For example, FIG. 16 shows two corners each having two capacitors. The capacitors 160, solder end caps 162 and dummy capacitors 164 may be used in any of the embodiments shown in FIG. 12-16, in any configuration described above. The capacitors 160, solder end caps 162 (by themselves) and/or dummy capacitors 164 are individually or collectively referred to herein as capacitor structures. While FIG. 12-16 show a single semiconductor device 150 secured by capacitors, multiple semiconductor devices 150 may be mounted on PCB 154, with one or more of them secured at its corners by capacitors 160.

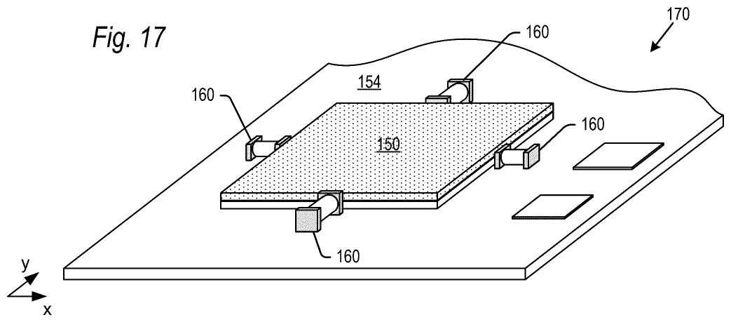

In embodiments described above, the semiconductor device 150 includes portions of support vias 120 at corners of the semiconductor device 150 for coupling with capacitors 160 at corners of the semiconductor device 150. However, it is conceivable in further embodiments that one or more of the capacitors are positioned to physically engage the semiconductor device 150 at sides of the semiconductor device between the corners. Such an embodiment is shown in FIG. 17. In this embodiment, instead of (or in addition to) forming the support vias 116 at corners of the semiconductor panel 102 as shown in FIG. 2, the support vias may be formed along one or more sides of the substrate 100 between the corners. Such an embodiment would provide additional structural support to the semiconductor device 150 mounted on the PCB 154, including at corners of the semiconductor device 150.

In the embodiment of FIG. 17, one or more of the capacitors 160 along the sides of the semiconductor device 150 may be replaced by solder end posts 162 (by themselves) or dummy capacitors 164. The embodiment of FIG. 17 may further include one or more capacitors 160, solder end posts 162 (by themselves) and/or dummy capacitors 160 at corners of the semiconductor device 150 according to any of the above-described embodiments.

In summary, in one example, the present technology relates to a semiconductor device, comprising: a substrate; a semiconductor die mounted on a first side of the substrate; electrical interconnections electrically coupling the semiconductor die to the substrate; and at least a portion of a support via, formed at one or more corners of the substrate, the support via specifically made to mate with a capacitor to mount the semiconductor device on a printed circuit board (PCB).

In another example, the present technology relates to a semiconductor assembly, comprising: a printed circuit board (PCB); a semiconductor device, comprising: a substrate, a semiconductor die mounted on a first side of the substrate, and electrical interconnections electrically coupling the semiconductor die to the substrate; and one or more capacitor structures, the one or more capacitor structures directly coupled to the semiconductor device to structurally support the semiconductor device on the substrate.

In a further example, the present technology relates to a semiconductor assembly, comprising: a printed circuit board (PCB); a semiconductor device, comprising: a substrate, a semiconductor die mounted on a first side of the substrate, and electrical interconnections electrically coupling the semiconductor die to the substrate; and means for mechanically and electrically supporting the semiconductor device on the PCB.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A semiconductor device, comprising:
a substrate;
a semiconductor die mounted on a first side of the substrate;
electrical interconnections electrically coupling the semiconductor die to the substrate; and
at least a portion of a support via, formed at one or more corners of the substrate, the support via specifically made to mate with a capacitor to mount the semiconductor device on a printed circuit board (PCB).

2. The semiconductor device of claim 1, wherein the at least a portion of the support via comprises a portion of a support via, a remaining portion of the support via removed upon singulation of the semiconductor device from a panel.

3. The semiconductor device of claim 1, wherein the at least a portion of the support via formed at one or more corners comprises the at least a portion of a support via formed at each of four corners of the semiconductor device.

4. The semiconductor device of claim 1, wherein the at least a portion of the support via extends from a first major surface of the substrate to a second major surface of the substrate opposed to the first major surface.

5. The semiconductor device of claim 1, wherein the at least a portion of the support via extends from a first major surface of the substrate but not to a second major surface of the substrate opposed to the first major surface.

6. The semiconductor device of claim 1, further comprising a plurality of solder balls on first major surface of the substrate opposite a second major surface of the substrate including the semiconductor die, the solder balls configured to electrically and mechanically couple the semiconductor device to the PCB.

7. The semiconductor device of claim 1, wherein the semiconductor die is a flash memory die.

8. The semiconductor device of claim 1, wherein the semiconductor die is a controller die.

9. A semiconductor assembly, comprising:
a printed circuit board (PCB);
a semiconductor device, comprising:
a substrate,
a semiconductor die mounted on a first side of the substrate, and
electrical interconnections electrically coupling the semiconductor die to the substrate; and
one or more capacitor structures, the one or more capacitor structures directly coupled to the semiconductor device to structurally support the semiconductor device on the substrate.

10. The semiconductor assembly of claim 9, wherein the capacitor structures comprise one or more of a capacitor having a pair of solder end posts, a solder end post by itself, and a dummy capacitor.

11. The semiconductor assembly of claim 9, wherein the capacitor structures comprise one or more capacitors, the one or more capacitors further providing electrical support to the semiconductor device.

12. The semiconductor assembly of claim 9, wherein the capacitor structures are positioned at one or more corners of the semiconductor device.

13. The semiconductor assembly of claim 12, wherein the capacitor structures are positioned at each of the corners of the semiconductor device.

14. The semiconductor assembly of claim 9 wherein the capacitor structures are positioned along one or more sides of the semiconductor device, between corners of the semiconductor device.

15. The semiconductor assembly of claim 9, further comprising a portion of a support vias formed in the substrate, a capacitor structure of the one or more capacitor structures coupling to the portion of the support via.

16. The semiconductor assembly of claim 15, wherein the capacitor structure comprises a solder post, the solder post supporting a bottom surface of the portion of the support via and a side surface of the portion of the support via.

17. The semiconductor assembly of claim 9, further comprising a plurality of solder balls on first major surface of the substrate opposite a second major surface of the substrate including the semiconductor die, the solder balls configured to electrically and mechanically couple the semiconductor device to the PCB.

18. The semiconductor assembly of claim 9, wherein the one or more capacitor structures comprise two or more capacitors, and wherein two of the two or more capacitors are oriented along different axes.

19. The semiconductor assembly of claim 9, wherein the one or more capacitor structures comprise two or more capacitors, and wherein two of the two or more capacitors are positioned adjacent to each other at a single corner.

20. A semiconductor assembly, comprising:
a printed circuit board (PCB);
a semiconductor device, comprising:
a substrate,
a semiconductor die mounted on a first side of the substrate, and
electrical interconnections electrically coupling the semiconductor die to the substrate; and
means for mechanically and electrically supporting the semiconductor device on the PCB.
